(19) United States
(12) Patent Application Publication
(10) Pub. No.: US 2013/0214235 A1
(43) Pub. Date: Aug. 22, 2013

(54) RESISTIVE MEMORY HAVING RECTIFYING CHARACTERISTICS OR AN OHMIC CONTACT LAYER

(71) Applicants: Jin Pyo Hong, Seoul (KR); Yoon Cheol Bae, Gyeongsangnam-do (KR); June Sik Kwak, Gyeonggi-do (KR); An Rahm Lee, Gyeongsangnam-do (KR)

(72) Inventors: Jin Pyo Hong, Seoul (KR); Yoon Cheol Bae, Gyeongsangnam-do (KR); June Sik Kwak, Gyeonggi-do (KR); An Rahm Lee, Gyeongsangnam-do (KR)

(73) Assignee: INDUSTRY-UNIVERSITY COOPERATION FOUNDATION HANYANG UNIVERSITY, Seoul (KR)

(21) Appl. No.: 13/881,584

(22) PCT Filed: Oct. 25, 2011
(86) PCT No.: PCT/KR11/07978

§ 371 Date: Apr. 25, 2013

(30) Foreign Application Priority Data
Oct. 26, 2010 (KR) 10-2010-0104600
Dec. 22, 2010 (KR) 10-2010-0132928

(51) Int. Cl. H01L 29/8605; H01L 45/00

(52) U.S. Cl. CPC H01L 29/8605; H01L 45/145
USPC 257/3

(57) ABSTRACT

Disclosed is a resistive memory simultaneously having rectifying characteristics and resistive characteristics according to a bias direction, wherein a resistive diode is interposed between electrodes at the top and bottom thereof. The resistive diode has a form in which a p-type resistive semiconductor layer is bonded to an n-type resistive semiconductor layer. When a high reverse bias is applied to the resistive diode, the resistive diode forms a conductive filament. When a forward bias is applied thereafter, a reset that destroys a portion of the formed conductive filament occurs, and as a result, a high resistance state is formed. Additionally, when a reverse bias is applied again, a set operation regenerating a conductive filament occurs. Thus, a low resistance state is achieved. Moreover, in order to achieve a resistive semiconductor layer and ohmic contact, and suppress the formation of a Schottky barrier, an ohmic contact layer is formed on the resistive diode. The present invention enables each memory cell to read information without misreading said information, even at a low readout voltage, and reduces the driving power required for a memory structure, such that a high-capacity and high-density memory is produced, and complexity and high costs of manufacturing processes may be avoided.

### TECHNICAL FIELD

The present invention relates to nonvolatile memories, and more particularly, to a resistive random access memory (ReRAM) having a diode structure.

### BACKGROUND ART

Recently, advancement in digital information and communication and household industry has led research on conventional nonvolatile memories based on control of electric charges to reach an uppermost limit. In other words, a nonvolatile memory configured based on electron mobility has reached an uppermost limit in terms of operating speed, power consumption, and degree of integration. Recently, research has been actively conducted on a memory using a status change in a material. New memories use a change in phase or magnetic field, i.e., a principle that a resistance value of a material is changed by inducing a status change in the material.

A flash memory, which is a representative nonvolatile memory, requires a high operating voltage during programming or erasing of data. Thus, when a flash memory is scaled down to 45 nm or less, a malfunction may occur due to interference between neighboring cells, low operating speeds, and high power consumption. In addition, a magnetic RAM (MRAM) is disadvantageous in that it has a complicated manufacturing process, a multilayered structure, and a low margin in a read/write operation.

A resistive random access memory (ReRAM) includes upper and lower electrodes having an oxide-based resistive layer interposed therebetween. The ReRAM operates based on a phenomenon in which a resistance value of the resistive layer is changed by applying a voltage thereto. In particular, since numbers of times data can be written to and read from the ReRAM are theoretically infinite, the ReRAM does not actually deteriorate, may operate at high speeds, and has excellent data stability. In particular, when an input pulse is supplied to the ReRAM, a time needed to change a resistance thereof to be 1000 times or more is 10 ns to 20 ns and the ReRAM can thus operate at high speeds.

The resistive layer of the ReRAM is a single film or a multilayer film, may be highly integrated, and may operate at high speeds. Also, the ReRAM may be manufactured using a process technology similar to a conventional complementary metal-oxide semiconductor (CMOS) process. The resistive layer is formed of a binary oxide or perovskite. When a process of initially applying a predetermined voltage (electro-forming) (hereinafter referred to as ‘forming’) is performed, a conductive filament is formed in the resistive layer. Also, the conductive filament is reset/set by controlling a voltage to be applied thereto. The ReRAM is operated as a nonvolatile memory by controlling current flowing through the resistive layer by resetting/setting the conductive filament.

Also, it is important to develop a cross-bar cell array having a memory cell size of 4F² so as to manufacture an ideal high-integrated memory device. However, interference occurs between neighboring cells due to unique characteristics of the cross-bar cell array. The interference becomes a factor that causes an error to occur during reading of data from a memory. To solve this problem, a selection device, such as diode or a transistor, which is capable of selectively reading data from cells, is included for each of the cells. A p-n junction diode, a Schottky diode, a transistor, etc. is used as the selection device.

However, the selection device disposed above or below the resistive layer is very complicated to manufacture. That is, an epitaxial process is indispensable to forming a diode or a transistor using a silicon-based semiconductor element. In addition to the epitaxial process, a process of patterning the silicon-based semiconductor element is additionally required. Also, the silicon-based semiconductor element is actually difficult to pattern using only one etch process since different films are disposed above and below the silicon-based semiconductor element.

Korean Patent Publication No. 2010-31698 discloses a ReRAM in which a diode is formed on a resistive layer. In particular, the diode uses a p-i-n junction, and is a polycrystalline silicon-based semiconductor element. In the case of the ReRAM, it is very technically difficult to perform an epitaxial process so as to form the polycrystalline silicon-based semiconductor element.

Korean Patent Publication No. 2010-45717 discloses a ReRAM including a resistive layer, an intermediate electrode, and an oxide diode. In particular, the oxide diode includes a p-type oxide layer formed of CuO, and an n-type oxide layer formed of InZnO. In the case of the ReRAM, a plurality of stacked structures are required, and a patterning process is difficult to perform due to a plurality of films.

Korean Patent Publication No. 2009-29558 discloses a diode that is a combination of oxide semiconductors. The oxide semiconductors that constitute the diode have metal-insulator transition(MIT) characteristics. The MIT characteristics are a phenomenon occurring in a material such as VO₂, in which a semiconductor assumes conductive properties due to thermal energy supplied to an oxide semiconductor (see Science Direct, accepted 25 Jul. 2005, “Abrupt metal-insulator transition observed in VO₂ thin films induced by a switching voltage pulse”). The diode including the oxide semiconductors is manufactured based on this phenomenon. Specifically, when a voltage that is equal to or higher than a threshold voltage is applied to a p or n-type oxide semiconductor, a resistance thereof is sharply lowered. Based on this principle, diode characteristics are realized. However, the oxide semiconductors are included to form the diode in a memory element, and not only the diode which is a switching element but also an additional resistance change element should be included to form a memory.

Also, when a ReRAM is manufactured having a p-n diode structure in a cross-bar cell array, the probability of an error occurring during reading of information, caused by neighboring devices is low but a Schottky barrier formed between an oxide and an electrode material increases a readout voltage applied during the reading of the information.

### DETAILED DESCRIPTION OF THE INVENTION

### Technical Problem

It is a first objective of the present invention to provide a resistive random access memory (ReRAM) in which an oxide p-n diode has resistance change characteristics to cause a change in a resistance using a simple structure and each of cells may be selectively accessed.

It is a second objective of the present invention to provide a ReRAM in which influences by neighboring devices even in a cross-bar cell array structure may be eliminated and an error may be prevented from occurring during reading of information using a simple structure.

### Technical Solution

To accomplish the first objective, the present invention provides a resistive random access memory including a lower electrode; a changeable resistance diode formed on the lower electrode; and an upper electrode formed on the changeable resistance diode. The changeable resistance diode has both rectifying characteristics obtained through a p-n junction and resistance change obtained by forming a conductive filament.

To accomplish the first objective, the present invention also provides a resistive random access memory including a lower electrode; a p-type changeable resistance semiconductor layer formed on the lower electrode; an n-type changeable resistance semiconductor layer configured to contact the p-type changeable resistance semiconductor layer; and an upper electrode formed on the n-type changeable resistance semiconductor layer. In the p-type changeable resistance semiconductor layer or the n-type changeable resistance semiconductor layer, forming which causes a conductive filament to be formed is performed by applying a bias thereto, rectifying characteristics occur, and the conductive filament is formed or destroyed.

To accomplish the second objective, the present invention provides a resistive random access memory including a lower electrode formed on a substrate; a changeable resistance diode formed on the lower electrode; and an upper electrode layer formed on the changeable resistance diode, and configured to form an ohmic contact with the changeable resistance diode.

To accomplish the second objective, the present invention also provides a resistive random access memory including a lower electrode formed on a substrate; an ohmic contact layer formed on the lower electrode and configured to form an ohmic contact with the lower electrode; a changeable resistance diode formed on the ohmic contact layer; and an upper electrode layer formed on the changeable resistance diode.

### Advantageous Effects

As described above, according to the present invention, a changeable resistance diode has both rectifying characteristics relating to cell selection and resistive characteristics relating to memory characteristics. A conductive filament is formed when a reverse bias is applied to a p-type changeable resistance semiconductor layer and an n-type changeable resistance semiconductor layer included in the changeable resistance diode. However, the conductive filament is formed not by simply applying the reverse bias but by performing electro-forming on a ReRAM to cause an effect such as soft breakdown to occur. Also, according to a structure introduced in the present invention, such electro-forming occurs only in a backward direction, not in a forward direction. Then, a set/reset operation of forming/destroying the conductive filament is repeatedly performed by repeatedly applying a reverse bias and a forward bias, thereby causing a change in a resistance state. The changeable resistance diode has not only the resistive characteristics but also rectifying characteristic that a relatively high amount of current flows through a changeable resistance diode when the forward voltage is applied thereto and a relatively low amount of current flows through the changeable resistance diode when the reverse voltage is applied thereto. Accordingly, a desired memory cell may be securely selectively selected through the rectifying characteristics.

Also, according to the present invention, an ohmic contact is formed on the changeable resistance diode. Thus, since a Schottky barrier may be suppressed from being generated due to the ohmic contact, not only may the rectifying characteristics be maintained in forward and backward directions but also high forward current may be obtained even when a low reverse bias is applied. An improvement in memory device characteristics of the changeable resistance diode using an ohmic contact layer enables information to be read from respective memory cells even at a low readout voltage without causing an error during the reading of the information. The improvement in the memory device characteristics ultimately reduces driving power to drive a whole memory structure, thereby realizing a large-capacity and high-density memory and reducing complexity and costs in a manufacturing process.

### BRIEF DESCRIPTION OF THE DRAWINGS

FIG. 1 is a cross-sectional view of a resistive random access memory (ReRAM) according to a first embodiment of the present invention.

FIGS. 2 to 4 are cross-sectional views illustrating a method of manufacturing the ReRAM according to the first embodiment of the present invention.

FIG. 5 is a graph showing voltage-current characteristics representing diode characteristics of the ReRAM according to the first embodiment of the present invention.

FIG. 6 is another graph showing voltage-current characteristics representing diode characteristics of the ReRAM according to the first embodiment of the present invention.

FIG. 7 is a graph showing operating characteristics of the ReRAM according to the first embodiment of the present invention.

FIG. 8 is a cross-sectional view of a ReRAM according to a second embodiment of the present invention.

FIGS. 9 to 11 are cross-sectional views illustrating a method of manufacturing the ReRAM according to the second embodiment of the present invention.

FIG. 12 is a graph showing voltage-current characteristics of the ReRAM including an ohmic contact layer according to the second embodiment of the present invention.

FIG. 13 is another graph showing voltage-current characteristics representing resistive switch characteristics of a diode of the ReRAM according to the second embodiment of the present invention.

### BEST MODE FOR CARRYING OUT THE INVENTION

Although a few embodiments of the present invention have been shown and described, it would be appreciated by those of ordinary skill in the art that changes may be made in these exemplary embodiments without departing from the principles and spirit of the invention, the scope of which is defined in the claims and their equivalents. Like reference numerals denote like elements throughout the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, exemplary embodiments of the present invention will be described in greater detail with reference to the accompanying drawings.

### First Embodiment

FIG. 1 is a cross-sectional view of a resistive random access memory (ReRAM) according to a first embodiment of the present invention.

Referring to FIG. 1, a lower electrode 110, a p-type changeable resistance semiconductor layer 121, an n-type changeable resistance semiconductor layer 123, and an upper electrode 130 are disposed on a substrate 100.

The type of the substrate 100 is not limited, provided it can be applied to a general semiconductor memory device. Thus, a material used to form the substrate 100 is not limited, and the substrate 100 may be a Si, SiO₂, or Si/SiO₂ multilayered substrate, a poly-silicon substrate, or the like.

Also, the substrate 100 may not be a physical substrate but be a specific film. That is, the substrate 100 may be a film formed on the physical substrate and capable of physically supporting the lower electrode 110 foamed in a subsequent process. The lower electrode 110 is formed on the substrate 100. The lower electrode 110 may be formed of a material selected from the group consisting of Pt, Au, Al, Cu, Ti, and an alloy thereof or may be a nitride-based electrode formed of TiN or WN. The lower electrode 110 may have a thickness of 20 nm to 200 nm according to a material selected to form the lower electrode 110.

A changeable resistance diode 120 is disposed on the lower electrode 110. The changeable resistance diode 120 includes the p-type changeable resistance semiconductor layer 121 and the n-type changeable resistance semiconductor layer 123.

First, the p-type changeable resistance semiconductor layer 121 is disposed on the lower electrode 110. The p-type changeable resistance semiconductor layer 121 includes CoOₓ (1≦X≦1.5, ‘x’ is a real number), MgOₓ (1≦x<2, ‘x’ is a real number), CuAlOₓ (1.8≦x<3, ‘x’ is a real number), MnOₓ (1≦x≦1.5, ‘x’ is a real number), SnOₓ (1.2≦x<2, ‘x’ is a real number), FeOₓ (1≦x≦1.5, ‘x’ is a real number), WOₓ (1.8≦x<3, ‘x’ is a real number), PbOₓ (1.2≦x<2, ‘x’ is a real number), Pr₁₋ₓCaₓMnO₃ (0.6≦x<1, ‘x’ is a real number), La₁₋ₓCaₓMnO₃ (0.6≦x<1, ‘x’ is a real number), La₁₋ₓSrₓMnO₃ (0.6≦x<1, ‘x’ is a real number), or PbZr₁₋ₓTiₓO₃ (0.6≦x<1, ‘x’ is a real number). In the p-type changeable resistance semiconductor layer 121, charge movement is mainly performed by holes. In particular, a material used to form the p-type changeable resistance semiconductor layer 121 preferably has a non-stoichiometric composition. In particular, hole movement is mainly performed by a vacancy of a metal element.

The n-type changeable resistance semiconductor layer 123 is disposed on the p-type changeable resistance semiconductor layer 121. The n-type changeable resistance semiconductor layer 123 with oxide includes TiOₓ (1.2≦x<1.89, ‘x’ is a real number), CeOₓ (1.5≦x<2, ‘x’ is a real number), ZnOₓ (1.2≦x<2, ‘x’ is a real number), TaOₓ (1.2≦x<2.5, ‘x’ is a real number), AlOₓ (1.2≦x<2, ‘x’ is a real number), LaOₓ (1.2≦x<2, ‘x’ is a real number), NbOₓ (1.2≦x≦2, ‘x’ is a real number), Sn-doped InOₓ (1≦x<1.5, ‘x’ is a real number), InₓZn₁₋ₓO₂ (0<x≦0.5, ‘x’ is a real number), LiₓNb₁₋ₓO₃ (0<x≦0.5, ‘x’ is a real number), SrₓTi₁₋ₓO₃ (0<x≦0.5, ‘x’ is a real number), BaₓSr₁₋ₓTiO₃ (0<x≦0.5, ‘x’ is a real number), Nb-doped SrₓTi₁₋ₓO₃ (0<x≦0.5, ‘x’ is a real number), Cr-doped SrₓTi₁₋ₓO₃ (0<x≦0.5, ‘x’ is a real number), SrₓZr₁₋ₓO₃ (0<x≦0.5, ‘x’ is a real number), or Cr-doped SrₓZr₁₋ₓO₃ (0<x≦0.5, ‘x’ is a real number). In the n-type changeable resistance semiconductor layer 123, charge movement is mainly performed by electrons. Thus, a material used to form the n-type changeable resistance semiconductor layer 123 preferably has a non-stoichiometric composition using a vacancy of an oxygen element.

The upper electrode 130 is disposed on the n-type changeable resistance semiconductor layer 123. The upper electrode 130 may be formed of a material selected from the group consisting of Pt, Au, Al, Cu, Ti, and an alloy thereof or may be a nitride-based electrode formed of TiN, or WN. The upper electrode 130 may be formed to a thickness of 20 nm to 200 nm, and may include a fine cross-bar array formed by performing patterning using a shadow mask or general photolithography, nano-imprinting, etc.

In FIG. 1, locations of the p-type changeable resistance semiconductor layer 121 with oxide and the n-type changeable resistance semiconductor layer 123 with oxide may be switched to each other. In other words, the n-type changeable resistance semiconductor layer 123 may be disposed on the lower electrode 110, and the p-type changeable resistance semiconductor layer 121 may be disposed on the n-type changeable resistance semiconductor layer 123.

Also, in FIG. 1, when the n-type changeable resistance semiconductor layer 123 and the p-type changeable resistance semiconductor layer 121 have the same carrier concentration, the thicknesses of the two changeable resistance semiconductor layers 121 and 123 are preferably different from each other. For example, a resistance change may mainly occur in a changeable resistance semiconductor layer having a larger thickness among the changeable resistance semiconductor layers 121 and 123 having different thicknesses.

Similarly, in FIG. 1, even if the n-type changeable resistance semiconductor layer 123 and the p-type changeable resistance semiconductor layer 121 have the same thickness, the carrier concentrations of the two changeable resistance semiconductor layers 121 and 123 are preferably set to be different. Thus, since a layer having a lower carrier concentration substantially becomes an insulating layer, a resistance change may mainly occur in the changeable resistance semiconductor layer.

A change between the carrier concentrations of the changeable resistance semiconductor layers 121 and 123 of different conductive types may be achieved by inducing a change in the concentration of a vacancy of either oxygen or a metal element. In particular, a change in the concentration of the vacancy of the metal element is preferably achieved by supplying oxygen of a non-stoichiometric composition.

Also, a resistance change in the changeable resistance semiconductor layers 121 and 123 may be achieved by forming a conductive filament by applying a high voltage thereto. That is, a resistance change occurs by forming or destroying a conductive filament acting as a moving path of electric charges in a material by applying a high voltage or bias thereto, rather than using a change in physical properties caused when thermal energy is supplied to the material, e.g., the MIT characteristics.

Diode characteristics are realized through a contact between the p-type changeable resistance semiconductor layer 121 and the n-type changeable resistance semiconductor layer 123. That is, even if a conductive filament is formed, the p-type changeable resistance semiconductor layer 121 and the n-type changeable resistance semiconductor layer 123 maintain rectifying characteristics using a p-n junction. Thus, the p-type changeable resistance semiconductor layer 121 and the n-type changeable resistance semiconductor layer 123 form the changeable resistance diode 120 maintaining diode characteristics and acting as a resistive layer. A resistance change is achieved by forming and destroying a conductive filament, rather than through the MIT characteristics. That is, according to the MIT characteristics, a process in which thermally energy is supplied into a material by supplying current thereto and a change in physical properties is induced by a temperature change occurring in the material occurs. In addition, the MIT characteristics occur due to various causes, e.g., movement of a doped metal element or a resistance change caused by Anderson localization that does or does not occur due to an irregular material composition. In contrast, a changeable resistance element uses a principle that a conductive filament is formed in a material by applying a bias thereto and electric charges move via the conductive filament.

Accordingly, a set operation of generating a conductive filament and a reset operation of destroying the conductive filament are not performed on a conventional diode having the MIT characteristics, and the conventional diode has different electrical characteristics from those of a changeable resistance element In the changeable resistance diode 120 according to an embodiment of the inventive concept, rectifying characteristics may be maintained by applying a voltage thereto in forward and backward directions, and a conductive filament may be repeatedly formed and destroyed by applying a specific bias thereto.

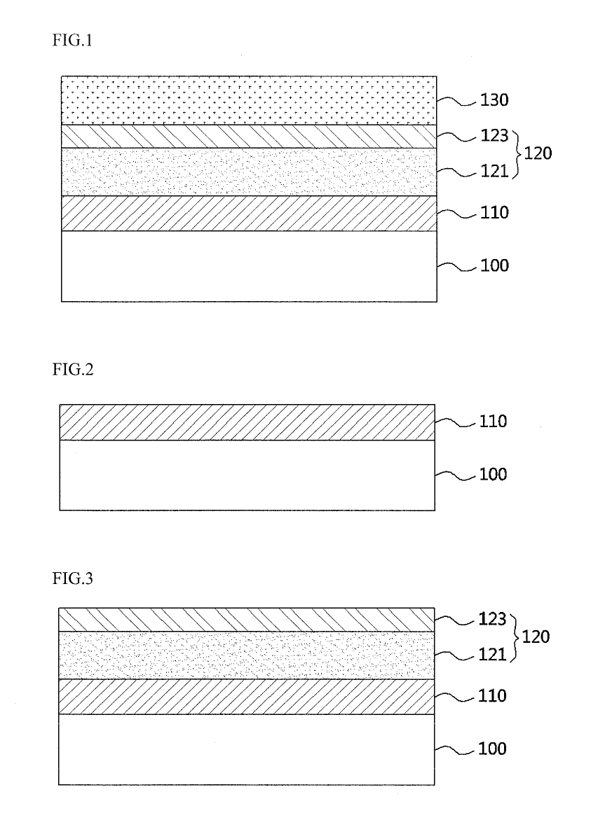

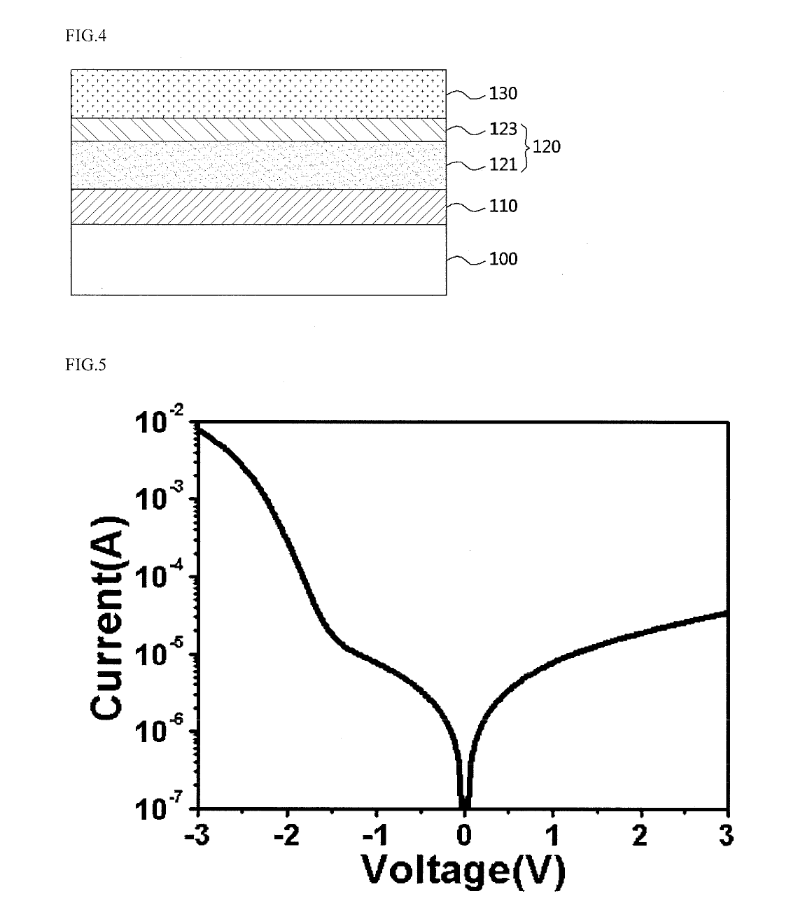

FIGS. 2 to 4 are cross-sectional views illustrating a method of manufacturing the ReRAM according to the first embodiment of the present invention.

Referring to FIG. 2, a lower electrode 110 is formed on a substrate 100. The substrate 100 may be a physical substrate or a specific film capable of physically supporting the lower electrode 110. The lower electrode 110 may be formed of a material selected from the group consisting of Pt, Au, Al, Cu, Ti, and an alloy thereof or may be a nitride-based electrode formed of TiN, or WN.

The lower electrode 110 may be formed using a general deposition method. In other words, the lower electrode 110 may be formed by physical vapor deposition, chemical vapor deposition, sputtering, pulse laser deposition, evaporation, electron beam deposition, atomic layer deposition, or molecular beam epitaxial deposition, etc. The lower electrode 110 may be preferably formed of TiN by sputtering.

Referring to FIG. 3, a changeable resistance diode 120 is formed on the lower electrode 110.

The amounts of current flowing through the changeable resistance diode 120 when a forward bias is applied thereto and when a reverse bias is applied thereto are different. Also, a resistance value of the changeable resistance diode 120 changes according to a voltage applied thereto. Thus, the changeable resistance diode 120 may perform a set/reset operation of forming/destroying a conductive filament according to a bias applied thereto, and may cause a cell to be selected according to unique diode characteristics.

Also, the changeable resistance diode 120 includes a p-type changeable resistance semiconductor layer 121 and an n-type changeable resistance semiconductor layer 123.

For example, the p-type changeable resistance semiconductor layer 121 is formed on the lower electrode 110. The p-type changeable resistance semiconductor layer 121 includes one of the materials described above with reference to FIG. 1. Also, the p-type changeable resistance semiconductor layer 121 may be formed according to any of various well-known deposition methods. For example, the p-type changeable resistance semiconductor layer 121 may be formed by physical vapor deposition, chemical vapor deposition, sputtering, pulse laser deposition, evaporation, electron beam deposition, atomic layer deposition, molecular beam epitaxial deposition, or the like. The p-type changeable resistance semiconductor layer 121 is preferably formed of CoOₓ.

The n-type changeable resistance semiconductor layer 123 is formed on the p-type changeable resistance semiconductor layer 121. The n-type changeable resistance semiconductor layer 123 includes one of the materials described above with reference to FIG. 1. Also, the n-type changeable resistance semiconductor layer 123 may be formed by any of the various deposition methods described above with respect to the forming of the p-type changeable resistance semiconductor layer 121. The n-type changeable resistance semiconductor layer 123 may be preferably formed using the method used to form the p-type changeable resistance semiconductor layer 121. Also, the n-type changeable resistance semiconductor layer 123 preferably includes TiOₓ.

Referring to FIG. 4, an upper electrode 130 is formed on the changeable resistance diode 120. The upper electrode 130 may be formed of a material selected from the group consisting of Pt, Au, Al, Cu, Ti, and an alloy thereof or may be a nitride-based electrode formed of TiN or WN. The upper electrode 130 may have a shape patterned using a shadow mask or general photolithography. For example, the upper electrode 130 may be formed by forming a conductive film for forming the upper electrode 130 by depositing a metal material, and patterning the conductive film by general photolithography. Otherwise, the upper electrode 130 having patterned morphology may be formed using a shadow mask during a deposition process.

After the upper electrode 130 is formed, post-heat treatment may be performed on a manufactured ReRAM.

FIG. 5 is a graph showing voltage-current characteristics representing diode characteristics of the ReRAM according to the first embodiment of the present invention.

Referring to FIG. 5, first, when poly-silicon is used to form a substrate, a lower electrode is formed directly on the substrate. The lower electrode is formed of Pt and to a thickness of 100 nm.

A changeable resistance diode is disposed on the lower electrode, and a p-type changeable resistance semiconductor layer is first formed on the lower electrode. The p-type changeable resistance semiconductor layer is formed of CoO and to a thickness of 30 nm. An n-type changeable resistance semiconductor layer is formed on the p-type changeable resistance semiconductor layer. The n-type changeable resistance semiconductor layer is formed of TiOₓ and to a thickness of 10 nm.

An upper electrode is formed on the changeable resistance diode, and includes Pt. The upper electrode is formed to a thickness of 100 nm.

Voltage is applied between upper and lower electrodes of the ReRAM having the above structure and current flowing through the upper and lower electrodes is measured. In FIG. 3, a negative value of voltage means a forward biased state, and a positive value of voltage means a reverse biased state. The ReRAM illustrated in FIG. 3 has a state in which a forming process has yet to be performed.

The changeable resistance diode forms high forward current when a forward voltage is applied thereto (marked by a ‘−’ unit). For example, forward current of 7.64 mA flows through the changeable resistance diode due to a voltage difference of 3 V. In contrast, when a reverse voltage (marked by a ‘+’ unit) is applied to the changeable resistance diode, a relatively low amount of reverse current flows through the changeable resistance diode. For example, reverse current of 34.6 uA flows through the changeable resistance diode due to a voltage difference of 3 V. As described above, the difference between the amounts of current flowing through the ReRAM when the forward bias is applied thereto and when the reverse bias is applied thereto via a changeable resistance diode including changeable resistance semiconductors is about 200 times or more. Thus, it is noted that the changeable resistance diode performs a predetermined rectifying operation with respect to directionality of a bias applied.

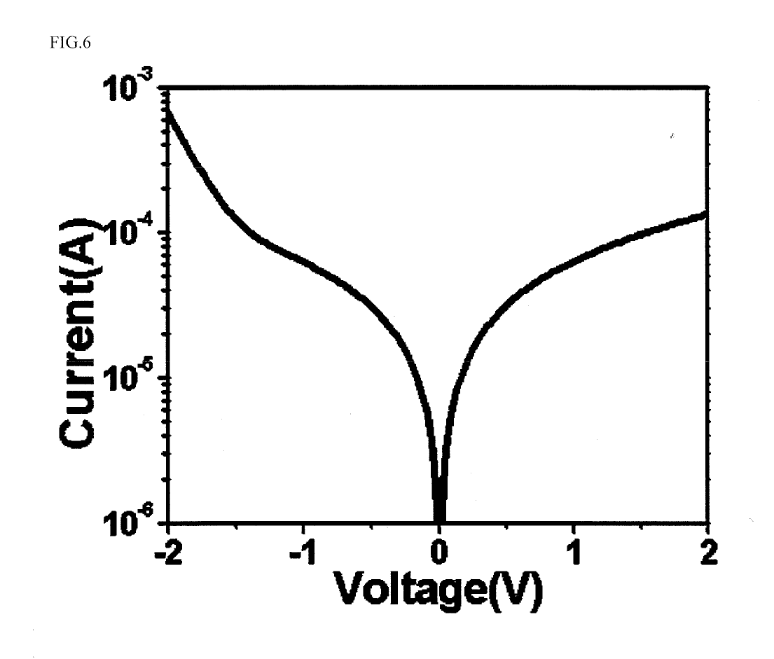

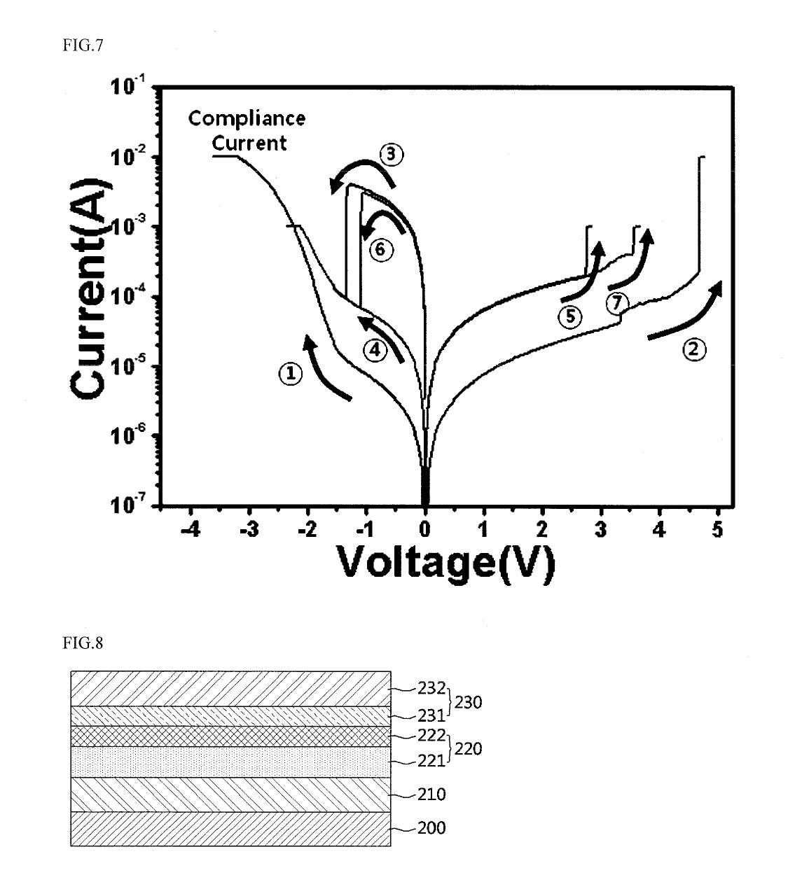

FIG. 6 is another graph showing voltage-current characteristics representing diode characteristics of the ReRAM according to the first embodiment of the present invention.

Referring to FIG. 6, forming is performed on the ReRAM described above with reference to FIG. 5, and diode characteristics of the ReRAM on which the forming is performed are measured. The forming is performed by applying a reverse bias to the ReRAM and occurs at about 4.6 V. Then, the reset operation is performed by applying a forward bias of 1.5 V. A conductive filament formed by the forming is partially destroyed through the reset operation. After the reset operation is performed, the set operation and the reset operation may be repeatedly performed on the ReRAM. Forward and reverse characteristics of the ReRAM on which the forming and the reset operation are performed are measured. In this case, the amount of current flowing when the forward bias is applied (marked by a ‘−’ unit) is larger than when the reverse bias (marked by a ‘+’ unit) is applied. In other words, even if the conductive filament is formed, rectifying characteristics according to a direction in which a bias is applied are maintained due to diode characteristics.

This is because a changeable resistance diode has both rectifying characteristics and resistive characteristics. That is, the conductive filament is formed in the changeable resistance diode, and a resistance change due to a generation and disappearance of the conductive filament and the rectifying characteristics due to the diode characteristics occur simultaneously.

FIG. 7 is a graph showing operating characteristics of the ReRAM according to the first embodiment of the present invention.

Referring to FIG. 7, a forward bias is applied to the ReRAM described above with reference to FIG. 5. When the forward bias is applied, a current increases as a voltage applied to the ReRAM increases (□). In other words, when only the forward bias is applied to the changeable resistance diode, a filament is not formed and only the current increases due to the increase in the voltage.

Then, a reverse bias is applied to the ReRAM. When a high reverse bias is applied to the ReRAM, forming occurs in the changeable resistance diode included therein. That is, the current sharply increases at about 4.6 V (□). This seems to be because the amount of current flowing through the changeable resistance diode is limited due to a diode characteristics of the changeable resistance diode when the reverse bias is applied, and a higher reverse bias than a forward bias is need to flow the same current as that of a forward bias. That is, when a low amount of current flows through the changeable resistance semiconductor element while a high reverse bias is applied thereto, a low resistance state occurs due to formation of a conductive filament in a bias state that is equal to or greater than a predetermined level.

When a forward bias is applied after the forming is performed, the changeable resistance diode maintains a very low resistance state. Also, when a bias is increased in the forward direction, the amount of current sharply decreases and the changeable resistance diode has a relatively high resistance state (□). This phenomenon is referred to as ‘resetting.’ This seems to be because a conductive filament formed during the forming is destroyed. Also, since the changeable resistance diode maintains a lower resistance state in graph □ than in graph □, it is noted that only the conductive filaments generated in the process marked by graph □ are partially destroyed.

When the forward bias is applied again, voltage-current characteristics occur due to an increased resistance state of the changeable resistance diode (□). That is, reset does not occur right after reset occurs once, even when the forward bias is applied again. This means that the reset operation is completed only once and does not further occur. The high resistance state of the changeable resistance diode is realized through the reset operation.

Also, the set operation is performed on the changeable resistance diode by applying a reverse voltage thereto (□). That is, a conductive filament is formed again on the changeable resistance diode by applying a high reverse bias thereto and the changeable resistance diode has a low resistance state. Accordingly, the low resistance state is maintained when the forward bias is applied.

If a high forward bias is applied to the changeable resistance diode that maintains the low resistance state and on which the set operation is performed, the changeable resistance diode is reset again (□). Through the reset operation, the changeable resistance diode having the low resistance state is switched to the high resistance state. The reset operation performed after the set operation described above is achieved by applying the reverse bias again to the changeable resistance diode (□).

As described above, the ReRAM according to the present embodiment may have both the diode characteristics and the resistive characteristics. That is, a desired element may be securely selectively selected using the rectifying characteristics of the ReRAM, and the changeable resistance diode may be switched between a low resistance state and a high resistance state by setting and resetting the selected element. In other words, not only may a desired element be selected but also writing/storing/reading of information may be performed using one changeable resistance diode. Accordingly, a device structure may be simplified, and complexity and high costs of a manufacturing process may be avoided.

### Second Embodiment

FIG. 8 is a cross-sectional view of a ReRAM according to a second embodiment of the present invention.

Referring to FIG. 8, a lower electrode 210, a changeable resistance diode 220, and an upper electrode layer 230 are disposed on a substrate 200. The changeable resistance diode 220 includes a p-type changeable resistance semiconductor layer 221 and an n-type changeable resistance semiconductor layer 222. The upper electrode layer 230 includes an ohmic contact layer 231 and an upper electrode 232.

The type of the substrate 200 is not limited, provided it can be applied to a general semiconductor memory device. Thus, a material used to form the substrate 200 is not limited, and the substrate 200 may be a Si, SiO₂, or Si/SiO₂ multilayered substrate, a poly-silicon substrate, or the like.

The substrate 200 may not be a physical substrate but may be a specific film. That is, the substrate 200 may be a film that is formed on the physical substrate, may have a predetermined stacked structure, and may be capable of physically supporting the lower electrode 210.

The lower electrode 210 is formed on the substrate 200. The lower electrode 210 may be formed of a material selected from the group consisting of Pt, Au, Al, Cu, Ti, and an alloy thereof or may be a nitride-based electrode formed of TiN or WN. The lower electrode 210 may have a thickness of 20 nm to 200 nm according to the material selected.

The changeable resistance diode 220 is disposed on the lower electrode 210. The changeable resistance diode 220 includes a p-type changeable resistance semiconductor layer 221 and an n-type changeable resistance semiconductor layer 222.

First, the p-type changeable resistance semiconductor layer 221 is formed on the lower electrode 210. The p-type changeable resistance semiconductor layer 221 includes CoOₓ (1≦x≦1.5, ‘x’ is a real number), MgOₓ (1≦x<2, ‘x’ is a real number), CuAlO, (1.8≦x<3, ‘x’ is a real number), MnOₓ (1≦x≦1.5, ‘x’ is a real number), SnOₓ (1.2≦x<2, ‘x’ is a real number), FeOₓ (1≦x≦1.5, ‘x’ is a real number), WOₓ (1.8≦x<3, ‘x’ is a real number), PbOₓ (1.2≦x<2, ‘x’ is a real number), Pr₁₋ₓCaₓMnO₃ (0.6≦x<1, ‘x’ is a real number), La₁₋ₓCaₓMnO₃ (0.6≦x<1, ‘x’ is a real number), La₁₋ₓSrₓMnO₃ (0.6≦x<1, ‘x’ is a real number), or PbZr₁₋ₓTiₓO₃ (0.6≦x<1, ‘x’ is a real number).

That is, the p-type changeable resistance semiconductor layer 221 is formed of an oxide semiconductor. In the p-type changeable resistance semiconductor layer 221, charge movement mainly performed by holes. In particular, the material used to form the p-type changeable resistance semiconductor layer 221 preferably has a non-stoichiometric composition. In particular, hole movement is mainly performed by a vacancy of a metal element.

The n-type changeable resistance semiconductor layer 222 is formed on the p-type changeable resistance semiconductor layer 221. The n-type changeable resistance semiconductor layer 222 includes TiOₓ (1.2≦x≦1.89, ‘x’ is a real number), CeOₓ (1.5≦x<2, ‘x’ is a real number), ZnOₓ (1.2≦x<2, ‘x’ is a real number), TaOₓ (1.2≦x<2.5, ‘x’ is a real number), AlOₓ (1.2≦x<2, ‘x’ is a real number), LaOₓ (1.2≦x<2, ‘x’ is a real number), NbOₓ (1.2≦x≦2, ‘x’ is a real number), Sn-doped InOₓ (1<x≦1.5, ‘x’ is a real number), InₓZn₁₋ₓO₂ (0<x≦0.5, ‘x’ is a real number), LiₓNb₁₋ₓO₃ (0<x≦0.5, ‘x’ is a real number), SrₓTi₁₋ₓO₃ (0<X≦0.5, ‘x’ is a real number), BaₓSr₁₋ₓTiO₃ (0<x≦0.5, ‘x’ is a real number), Nb-doped SrₓTi₁₋ₓO₃ (0<x≦0.5, ‘x’ is a real number), Cr-doped SrₓZr₁₋ₓO₃ (0<x≦0.5, ‘x’ is a real number), SrₓZr₁₋ₓO₃ (0<x≦0.5, ‘x’ is a real number), or Cr-doped SrₓZr₁₋ₓO₃ (0<x≦0.5, ‘x’ is a real number).

The n-type changeable resistance semiconductor layer 222 is formed of an oxide semiconductor. In the n-type changeable resistance semiconductor layer 222, charge movement is mainly performed by electrons. Thus, the n-type changeable resistance semiconductor layer 222 has a non-stoichiometric composition using a vacancy of an oxygen element.

The upper electrode layer 230 is formed on the n-type changeable resistance semiconductor layer 222.

In particular, the ohmic contact layer 231 is formed on the n-type changeable resistance semiconductor layer 222 to suppress formation of a Schottky barrier. The ohmic contact layer 231 is formed of a conductive material, and forms an ohmic contact together with the n-type changeable resistance semiconductor layer 222. The ohmic contact layer 231 includes a metal material having a relatively low work function, such as Al, In, Ti, or Mn; a nitride material, such as WN or TiN; or an oxide electrode material, such as TiOₓ (0.5<x<1.4), (In,Sn)₂O₃, RuO₂, or SrRuO₃. The ohmic contact layer 231 preferably has a thickness of 3 nm to 250 nm. If the ohmic contact layer 231 has a thickness of less than 3 nm, an effect of suppressing the formation of the Schottky barrier is lowered. If the ohmic contact layer 231 has a thickness of more than 250 nm, diode characteristics of a device may be influenced by the ohmic contact layer 231 or the size of a whole device may increase. In particular, the n-type changeable resistance semiconductor layer 222 is formed of TiOₓ (1.2≦x≦1.89, ‘x’ is a real number), the ohmic contact layer 231 is preferably formed of the same material, i.e., TiOₓ (0.5<x<1.4).

The upper electrode 232 is formed on the ohmic contact layer 231. The upper electrode 232 may be formed of a material selected from the group consisting of Pt, Au, Al, Cu, Ti, and an alloy thereof or may be a nitride-based electrode formed of TiN or WN. The upper electrode 232 may be formed to a thickness of 20 nm to 200 nm, and may be formed as a fine cross-bar array formed by performing patterning using a shadow mask or general photolithography, nano printing, or e-beam lithography, or the like. That is, the lower electrode 210 and the upper electrode 232 may be formed such that they extend to intersect each other.

In FIG. 8, the locations of the p-type changeable resistance semiconductor layer 221 and the n-type changeable resistance semiconductor layer 222 may be switched. That is, the n-type changeable resistance semiconductor layer 222 may be first formed on the ohmic contact layer 231 on the lower electrode 210, and the p-type changeable resistance semiconductor layer 221 may be disposed on the n-type changeable resistance semiconductor layer 222.

A change in resistances of the changeable resistance semiconductor layers 221 and 222 is performed by forming and destroying a conductive filament by applying a voltage thereto. That is, such a resistance change is caused by forming and destroying the conductive filament acting as a moving path of electric charges in an element by applying a high voltage or bias thereto.

Also, a contact between the p-type changeable resistance semiconductor layer 221 and the n-type changeable resistance semiconductor layer 222 has diode characteristics. That is, even if a conductive filament is formed, the p-type changeable resistance semiconductor layer 221 and the n-type changeable resistance semiconductor layer 222 form the changeable resistance diode 220 that maintains the diode characteristics and that acts as a resistive layer together.

FIGS. 9 to 11 are cross-sectional views illustrating a method of manufacturing the ReRAM according to the second embodiment of the present invention.

Referring to FIG. 9, a lower electrode 210 is formed on a substrate 200. The substrate 200 may be a physical substrate or may be a specific film capable of supporting the lower electrode 210. The lower electrode 210 may be formed of a material selected from the group consisting of Pt, Au, Al, Cu, Ti and an alloy thereof or may be a nitride-based electrode formed of TiN or WN.

The lower electrode 210 may be formed using a general deposition method. In other words, the lower electrode 210 may be formed by physical vapor deposition, chemical vapor deposition, sputtering, pulse laser deposition, evaporation, electron beam deposition, atomic layer deposition, or molecular beam epitaxial deposition, etc. The lower electrode 210 may be preferably formed of Pt by sputtering.

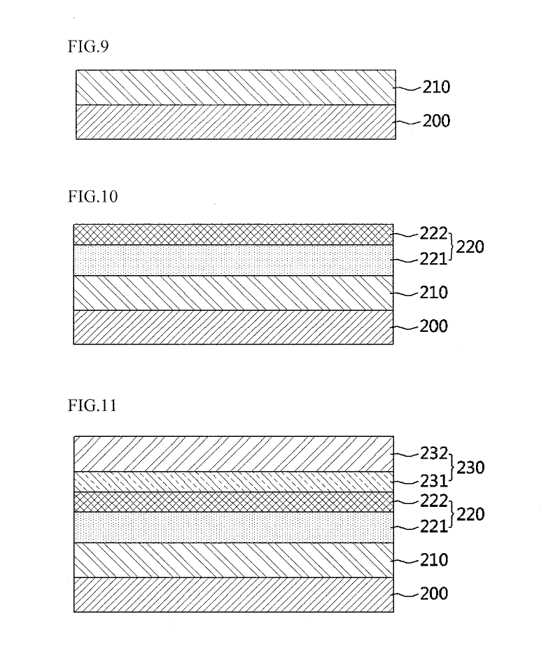

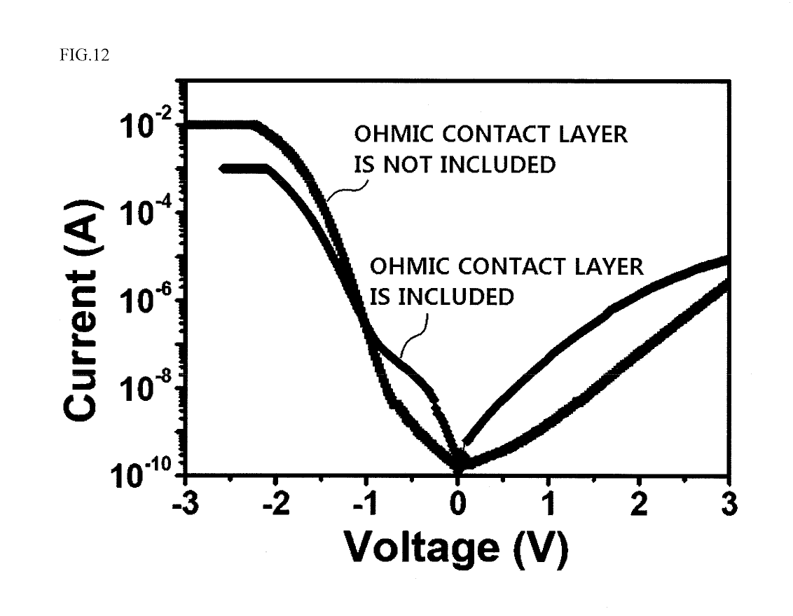

Referring to FIG. 10, the changeable resistance diode 220 is formed on the lower electrode 210. The amount of current flowing through the changeable resistance diode 220 when a forward bias is applied thereto is different from when a reverse bias is applied thereto. Also, the changeable resistance diode 220 has characteristics that a resistance value thereof changes due to a voltage applied thereto. Thus, the changeable resistance diode 220 may perform a set/reset operation of forming/destroying a conductive filament according to a bias applied thereto, and may cause a desired cell to be selected according to unique diode characteristics.

The changeable resistance diode 220 includes a p-type changeable resistance semiconductor layer 221 and an n-type changeable resistance semiconductor layer 222.

For example, the p-type changeable resistance semiconductor layer 221 is formed on the lower electrode 210. The p-type changeable resistance semiconductor layer 221 includes any of the materials described above with reference to FIG. 8. The p-type changeable resistance semiconductor layer 221 may be formed according to any of various well-known deposition methods.

For example, the p-type changeable resistance semiconductor layer 221 may be formed by physical vapor deposition, chemical vapor deposition, sputtering, pulse laser deposition, evaporation, electron beam deposition, atomic layer deposition, molecular beam epitaxial deposition, or the like. The p-type changeable resistance semiconductor layer 221 is preferably formed of CoOₓ.

The n-type changeable resistance semiconductor layer 222 is formed on the p-type changeable resistance semiconductor layer 221. The n-type changeable resistance semiconductor layer 222 includes any of the materials described above with reference to FIG. 8. The n-type changeable resistance semiconductor layer 222 may be formed according to any of various deposition methods as described above with respect to the formation of the p-type changeable resistance semiconductor layer 221. The n-type changeable resistance semiconductor layer 222 is preferably formed according to the same method used to form the p-type changeable resistance semiconductor layer 221. Also, the n-type changeable resistance semiconductor layer 222 preferably includes TiOₓ (1.2≦x<1.89, ‘x’ is a real number).

Referring to FIG. 11, an upper electrode layer 230 is formed on the changeable resistance diode 220. The upper electrode layer 230 includes an ohmic contact layer 231 and an upper electrode 232. In particular, the ohmic contact layer 231 is first formed on the changeable resistance diode 220. The ohmic contact layer 231 includes a metal material having a relatively low work function, such as Al, In, Ti, or Mn; a nitride material, such as WN or TiN; or an oxide electrode material, such as TiOₓ (0.5<x<1.4), (In,Sn)₂O₃, RuO₂, or SrRuO₃. The ohmic contact layer 231 preferably has a thickness of 3 nm to 250 nm. If the ohmic contact layer 231 has a thickness of less than 3 nm, an effect of suppressing the formation of a Schottky barrier is lowered. If the ohmic contact layer 231 has a thickness of more than 250 nm, diode characteristics of a device may be influenced by the ohmic contact layer 231 or the size of a whole device may increase. In particular, when the n-type changeable resistance semiconductor layer 222 is formed of TiOₓ (1.2≦x≦1.89, ‘x’ is a real number), the ohmic contact layer 231 is preferably formed of the same material, i.e., TiOₓ (0.5<x<1.4).

Also, the ohmic contact layer 231 may have a shape patterned using a shadow mask, general photolithography, or e-beam lithography. For example, the ohmic contact layer 231 may be formed by forming a conductive film for forming the ohmic contact layer 231 by depositing a metal material, and patterning the conductive film by general photolithography. Otherwise, the ohmic contact layer 231 having patterned morphology may be formed using a shadow mask during a deposition process.

In particular, when the n-type changeable resistance semiconductor layer 222 is formed of TiOₓ (1.2≦x≦1.89, ‘x’ is a real number), the ohmic contact layer 231 is preferably formed of TiOₓ.

The upper electrode 232 is formed on the ohmic contact layer 231. The upper electrode 232 may be formed of a material selected from the group consisting of Pt, Au, Al, Cu, Ti, and an alloy thereof or may be a nitride-based electrode formed of TiN or WN. Also, the upper electrode 232 may have a shape patterned by a shadow mask or general photolithography. For example, the upper electrode 232 may be formed by forming a conductive film for forming the upper electrode 232 by depositing a metal material, and patterning the conductive film by general photolithography. Otherwise, the upper electrode 232 having patterned morphology may be formed using a shadow mask during a deposition process.

After the upper electrode 232 is formed, post-heat treatment may be performed on a manufactured ReRAM.

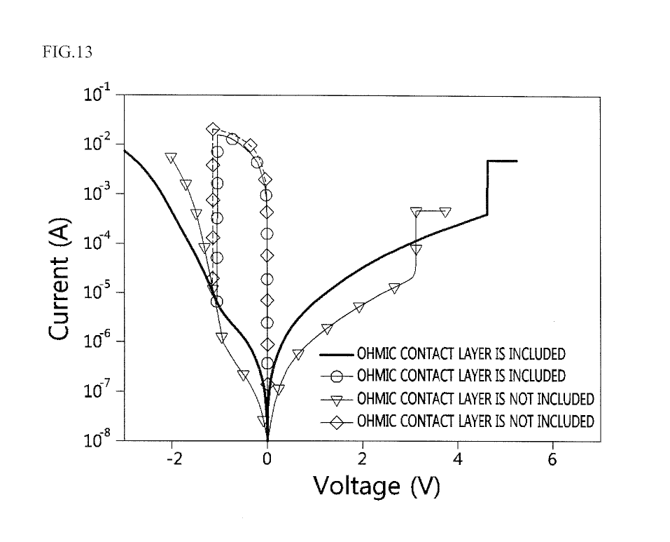

FIG. 12 is a graph showing voltage-current characteristics of the ReRAM including an ohmic contact layer according to the second embodiment of the present invention.

Referring to FIG. 12, a substrate is formed of poly-silicon and a lower electrode is formed directly on the substrate. The lower electrode is formed of Pt and to a thickness of 100 nm.

A changeable resistance diode is disposed on the lower electrode, and a p-type changeable resistance semiconductor layer is first formed on the lower electrode. The p-type changeable resistance semiconductor layer includes CoO and is formed to a thickness of 30 nm. Also, an n-type changeable resistance semiconductor layer is formed on the p-type changeable resistance semiconductor layer. The n-type changeable resistance semiconductor layer is formed of TiOₓ (1.2≦x≦1.89, ‘x’ is a real number) and to a thickness of 10 nm.

On the changeable resistance diode, an ohmic contact layer is formed of TiOₓ (0.5<x<1.4) and to a thickness of 5 nm. An upper electrode formed on the ohmic contact layer includes Pt. The upper electrode is formed to a thickness of 100 nm.

Voltage is applied between upper and lower electrodes of the ReRAM having the above structure and current flowing through the upper and lower electrodes is measured. A negative value of voltage means a forward biased state, and a positive value of voltage means a reverse biased state. The ReRAM illustrated in FIG. 12 has a state in which a forming process has yet to be performed.

In the case of a changeable resistance diode element into which the ohmic contact layer is inserted, the changeable resistance diode forms a high forward current by applying the forward voltage (marked by a ‘−’ unit) thereto. For example, a forward current of 1 mA or more flows through the changeable resistance diode due to a voltage difference of 2 V. However, when the reverse voltage (marked by a ‘+’ unit) is applied to the changeable resistance diode, a low amount of reverse current flows due to rectifying characteristics. For example, reverse current of 1 mA or less flows through the changeable resistance diode due to a voltage difference of 2 V. As described above, the difference between the amounts of current flowing through the ReRAM when the forward bias is applied thereto and when the reverse bias is applied thereto via the changeable resistance diode including changeable resistance semiconductors is about 1000 times or more. Thus, the changeable resistance diode performs a rectifying operation with respect to directionality of a bias applied thereto. In particular, when the amount of forward current in a low voltage region, e.g., a region or 0.5 V or less, is considered, the amount of the forward current in a changeable resistance diode element into which an ohmic contact layer is inserted is much larger than in a changeable resistance diode element into which an ohmic contact layer is not inserted. This is due to whether a Schottky barrier is present between an electrode material and a resistive material. The inserted ohmic contact layer suppresses formation of the Schottky barrier and forms ohmic contact so that a high amount of forward current may flow even at a low voltage when the forward bias is applied.

FIG. 13 is another graph showing voltage-current characteristics representing resistive switch characteristics of a diode of the ReRAM according to the second embodiment of the present invention.

Referring to FIG. 13, forming is performed on the ReRAM illustrated in FIG. 12, and diode characteristics of the ReRAM on which the forming is performed are measured. The forming is performed by applying the reverse bias and occurs at about 4.6 V. Then, the reset operation is performed by applying a forward bias of 1.5 V. A conductive filament formed by the forming is partially destroyed through the reset operation.

The set and reset operations may be repeatedly performed on the ReRAM on which the reset operation is performed. Forward and backward characteristics of the resistive random access memory on which the forming and the reset operation are performed are measured. The amount of current when the forward bias (marked by a ‘−’ unit) is formed is larger than when the reverse bias (marked by a ‘+’ unit) is applied. In particular, the amount of current in a forward low voltage region (<0.5 V), which reads information from the ReRAM, in an HRS state when the ohmic contact layer is inserted is larger than when the ohmic contact layer is not inserted by ten times or more. This means that information may be read from a memory cell at a low readout voltage during operation of the ReRAM.

As described above, in a ReRAM having both diode characteristics and resistive characteristics according to the present invention, an ohmic contact layer is used to suppress formation of a Schottky barrier, thereby enabling a high forward current to be obtained even at a low forward bias while maintaining rectifying characteristics in both the forward and backward directions. An improvement in the characteristics of the ReRAM owing to the ohmic contact layer allows information to be read from each of memory cells even at a low readout voltage without causing an error during the reading of the information. The improvement in the characteristics of the ReRAM finally decreases driving power to drive a whole memory structure, thereby realizing a large-capacity and high-density memory and reducing complexity and costs in a manufacturing process.

1. A resistive random access memory comprising:
a lower electrode;
a changeable resistance diode formed on the lower electrode; and
an upper electrode formed on the changeable resistance diode,
wherein the changeable resistance diode has both rectifying characteristics obtained through a p-n junction and resistance change obtained by forming a conductive filament.

2. The resistive random access memory of claim 1, wherein the changeable resistance diode comprises:
a p-type changeable resistance semiconductor layer formed on the lower electrode; and
an n-type changeable resistance semiconductor layer formed on the p-type changeable resistance semiconductor layer.

3. The resistive random access memory of claim 2, wherein the p-type changeable resistance semiconductor layer comprises CoOₓ (1≦x≦1.5, ‘x’ is a real number), MgOₓ (1≦x<2, ‘x’ is a real number), CuAlOₓ (1.8≦x<3, ‘x’ is a real number), MnOₓ (1≦x≦1.5, ‘x’ is a real number), SnOₓ (1.2≦x<2, ‘x’ is a real number), FeOₓ (1≦x≦1.5, ‘x’ is a real number), WOₓ (1.8≦x<3, ‘x’ is a real number), PbOₓ (1.2≦x<2, ‘x’ is a real number), Pr₁₋ₓCaₓMnO₃ (0.6≦x<1, ‘x’ is a real number), La₁₋ₓCaₓMnO₃ (0.6≦x<1, ‘x’ is a real number), La₁₋ₓSrₓMnO₃ (0.6≦x<1, ‘x’ is a real number), or PbZr₁₋ₓTi₃O₃ (0.6≦x<1, ‘x’ is a real number), and
hole movement is mainly performed by a vacancy of a metal element.

4. The resistive random access memory of claim 2, wherein the n-type changeable resistance semiconductor layer comprises TiOₓ (1.2≦x≦1.89, ‘x’ is a real number), CeOₓ (1.5≦x<2, ‘x’ is a real number), ZnOₓ (1.2≦x<2, ‘x’ is a real number), TaOₓ (1.2≦x<2.5, ‘x’ is a real number), AlOₓ (1.2≦x<2, ‘x’ is a real number), LaOₓ (1.2≦x<2, ‘x’ is a real number), NbOₓ (1.2≦x≦2, ‘x’ is a real number), Sn-doped InOₓ (1<x≦1.5, ‘x’ is a real number), InₓZn₁₋ₓO₂ (0<x≦0.5, ‘x’ is a real number), LiₓNb₁₋ₓO₃ (0<x≦0.5, ‘x’ is a real number), SrₓTi₁₋ₓO₃ (0<x≦0.5, ‘x’ is a real number), BaₓSr₁₋ₓTiO₃ (0<x≦0.5, ‘x’ is a real number), Nb-doped SrₓTi₁₋ₓO₃ (0<x≦0.5, ‘x’ is a real number), Cr-doped SrₓTi₁₋ₓO₃ (0<x≦0.5, ‘x’ is a real number), SrₓZr₁₋ₓO₃ (0<x≦0.5, ‘x’ is a real number), or Cr-doped SrₓZr₁₋ₓO₃ (0<x≦0.5, ‘x’ is a real number), and
electron movement is mainly performed by a vacancy of an oxygen element.

5. The resistive random access memory of claim 2, wherein the conductive filament is formed in the p-type changeable resistance semiconductor layer or the n-type changeable resistance semiconductor layer by applying a bias thereto.

6. The resistive random access memory of claim 1, wherein the lower electrode or the upper electrode is formed of a material selected from the group consisting of Pt, Au, Al, Cu, Ti, and an alloy thereof, or is a nitride-based electrode formed of TiN or WN,

7. A resistive random access memory comprising:
a lower electrode;
a p-type changeable resistance semiconductor layer formed on the lower electrode;
an n-type changeable resistance semiconductor layer configured to contact the p-type changeable resistance semiconductor layer; and
an upper electrode formed on the n-type changeable resistance semiconductor layer,
wherein, in the p-type changeable resistance semiconductor layer or the n-type changeable resistance semiconductor layer, forming which causes a conductive filament to be formed is performed by applying a bias thereto, rectifying characteristics occur, and the conductive filament is formed or destroyed.

8. The resistive random access memory of claim 7, wherein the p-type changeable resistance semiconductor layer has a different carrier concentration or thickness from the n-type changeable resistance semiconductor layer.

9. The resistive random access memory of claim 7, wherein, in the p-type changeable resistance semiconductor layer or the n-type changeable resistance semiconductor layer, the conductive filament is destroyed by applying a forward bias or is formed by applying a reverse bias, after the forming is performed thereon.

10. The resistive random access memory of claim 7, wherein the p-type changeable resistance semiconductor layer comprises CoOₓ (1≦x≦1.5, ‘x’ is a real number), MgOₓ (1≦x<2, ‘x’ is a real number), CuAlOₓ (1.8≦x<3, ‘x’ is a real number), MnOₓ (1≦x<1.5, ‘x’ is a real number), SnOₓ (1.2≦x<2, ‘x’ is a real number), FeOₓ (1≦x≦1.5, ‘x’ is a real number), WOₓ (1.8≦x<3, ‘x’ is a real number), PbOₓ (1.2≦x<2, ‘x’ is a real number), Pr₁₋ₓCaₓMnO₃ (0.6≦x<1, ‘x’ is a real number), La₁₋ₓCaₓMnO₃ (0.6≦x<1, ‘x’ is a real number), La₁₋ₓSrₓMnO₃ (0.6≦x<1, ‘x’ is a real number), or PbZr₁₋ₓTiₓO₃ (0.6≦x<1, ‘x’ is a real number), and
hole movement is mainly performed by a vacancy of a metal element.

11. The resistive random access memory of claim 7, wherein the n-type changeable resistance semiconductor layer comprises TiOₓ (1.2≦x≦1.89, ‘x’ is a real number), CeOₓ (1.5≦x<2, ‘x’ is a real number), ZnOₓ (1.2≦x<2, ‘x’ is a real number), TaOₓ (1.2≦x<2.5, ‘x’ is a real number), AlOₓ (1.2≦x<2, ‘x’ is a real number), LaOₓ (1.2≦x<2, ‘x’ is a real number), NbOₓ (1.2≦x≦2, ‘x’ is a real number), Sn-doped InOₓ (1<x≦1.5, ‘x’ is a real number), InₓZn₁₋ₓO₂ (0<x≦0.5, ‘x’ is a real number), LiₓNb₁₋ₓO₃ (0<x≦0.5, ‘x’ is a real number), SrₓTi₁₋ₓO₃ (0<x≦0.5, ‘x’ is a real number), BaₓSr₁₋ₓTiO₃(0<x≦0.5, ‘x’ is a real number), Nb-doped SrₓTi₁₋ₓO₃ (0<x≦0.5, ‘x’ is a real number), Cr-doped SrₓTi₁₋ₓO₃ (0<x≦0.5, ‘x’ is a real number), SrₓZr₁₋ₓO₃ (0<x≦0.5, ‘x’ is a real number), or Cr-doped SrₓZr₁₋ₓO₃(0<x≦0.5, ‘x’ is a real number), and
electron movement is mainly performed by a vacancy of an oxygen element.

12. A resistive random access memory comprising:
a lower electrode formed on a substrate;
a changeable resistance diode formed on the lower electrode; and
an upper electrode layer formed on the changeable resistance diode, and configured to form an ohmic contact with the changeable resistance diode.

13. The resistive random access memory of claim 12, wherein the changeable resistance diode comprises:
a p-type changeable resistance semiconductor layer formed on the lower electrode, and formed of an oxide semiconductor in which charge movement is mainly performed by holes; and
an n-type changeable resistance semiconductor layer formed on the p-type changeable resistance semiconductor layer, and formed of an oxide semiconductor in which charge movement is mainly performed by electrons.

14. The resistive random access memory of claim 13, wherein the p-type changeable resistance semiconductor layer has a non-stoichiometric composition, has a vacancy of a metal element, and comprises CoOₓ (1≦x≦1.5, ‘x’ is a real number), MgOₓ (1≦x<2, ‘x’ is a real number), CuAlOₓ (1.8≦x<3, ‘x’ is a real number), MnOₓ (1≦x≦1.5, ‘x’ is a real number), SnOₓ (1.2≦x<2, ‘x’ is a real number), FeOₓ (1≦x≦1.5, ‘x’ is a real number), WOₓ (1.8≦x<3, ‘x’ is a real number), PbOₓ (1.2≦x<2, ‘x’ is a real number), Pr₁₋ₓCaₓMnO₃ (0.6≦x<1, ‘x’ is a real number), La₁₋ₓCaₓMnO₃ (0.6≦x<1, ‘x’ is a real number), La₁₋ₓSrₓMnO₃ (0.6≦x<1, ‘x’ is a real number), or PbZr₁₋ₓTiₓO₃ (0.6≦x<1, ‘x’ is a real number).

15. The resistive random access memory of claim 13, wherein the n-type changeable resistance semiconductor layer has a non-stoichiometric composition, has a vacancy of an oxygen element, and comprises TiOₓ (1.2≦x≦1.89, ‘x’ is a real number), CeOₓ (1.5≦x<2, ‘x’ is a real number), ZnOₓ (1.2≦x<2, ‘x’ is a real number), TaOₓ (1.2≦x<2.5, ‘x’ is a real number), AlOₓ (1.2≦x<2, ‘x’ is a real number), LaOₓ (1.2≦x<2, ‘x’ is a real number), NbOₓ (1.2≦x≦2, ‘x’ is a real number), Sn-doped InOₓ (1<x≦1.5, ‘x’ is a real number), InₓZn₁₋ₓO₂ (0<x≦0.5, ‘x’ is a real number), LiₓNb₁₋ₓO₃ (0<x≦0.5, ‘x’ is a real number), SrₓTi₁₋ₓO₃ (0<x≦0.5, ‘x’ is a real number), BaₓSr₁₋ₓTiO₃ (0<x≦0.5, ‘x’ is a real number), Nb-doped SrₓTi₁₋ₓO₃ (0<x≦0.5, ‘x’ is a real number), Cr-doped SrₓTi₁₋ₓO₃ (0<x≦0.5, ‘x’ is a real number), SrₓZr₁₋ₓO₃ (0<x≦0.5, ‘x’ is a real number), or Cr-doped SrₓZr₁₋ₓO₃ (0<x≦0.5, ‘x’ is a real number).

16. The resistive random access memory of claim 13, wherein the upper electrode layer comprises:
an ohmic contact layer formed on the n-type changeable resistance semiconductor layer and configured to suppress formation of a Schottky barrier with the changeable resistance diode; and
an upper electrode formed on the ohmic contact layer.

17. The resistive random access memory of claim 16, wherein the ohmic contact layer comprises a metal material such as Al, In, Ti, or Mn; a nitride material such as WN or TiN; or an oxide electrode material such as TiOₓ (0.5<x<1.4), (In,Sn)₂O₃, RuO₂, or SrRuO₃.

18. A resistive random access memory comprising:
a lower electrode formed on a substrate;
an ohmic contact layer formed on the lower electrode and configured to form an ohmic contact with the lower electrode;
a changeable resistance diode formed on the ohmic contact layer; and
an upper electrode layer formed on the changeable resistance diode.

19. The resistive random access memory of claim 18, wherein the changeable resistance diode comprises:
an n-type changeable resistance semiconductor layer formed on the ohmic contact layer and formed of an oxide semiconductor in which charge movement is mainly performed by electrons; and
a p-type changeable resistance semiconductor layer formed on the n-type changeable resistance semiconductor layer and formed of an oxide semiconductor in which charge movement is mainly performed by holes.

20. The resistive random access memory of claim 18, wherein the ohmic contact layer comprises a metal material such as Al, In, Ti, or Mn; a nitride material such as WN or TiN; or an oxide electrode material such as TiOₓ (0.5<x<1.4), (In,Sn)₂O₃, RuO₂, or SrRuO₃
